(19) United States
(12) Patent Application Publication
(10) Pub. No.: US 2004/0241995 A1
(43) Pub. Date: Dec. 2, 2004

(54) Etching apparatus and etching method

(75) Inventor: Michinari Yamanaka, Osaka (JP)

Correspondence Address: Jack Q. Lever, Jr., McDERMOTT, WILL & EMERY, 600 Thirteenth Street, N.W., Washington, DC, 20005-3096, US

(73) Assignee: MATSUSHITA ELECTRIC INDUSTRIAL CO., LTD.

(21) Appl. No.: 10/807,191

(22) Filed: Mar. 24, 2004

(30) Foreign Application Priority Data
Mar. 27, 2003 (JP) 2003-086680

(51) Int. Cl. H01L 21/302; H01L 21/461

(52) U.S. Cl. 438/689

(57) ABSTRACT

An etching apparatus includes a shield device provided on an electrode in a reaction chamber and surrounding an object to be etched. The shield device has a surface area according to an opening area ratio of the object to be etched.

### BACKGROUND OF THE INVENTION

The present invention relates to etching apparatus and etching methods.

FIG. 12 schematically shows a conventional dry etching apparatus for use in etching of an oxide film or other films.

As shown in FIG. 12, a substrate 20 to be processed is mounted on a lower electrode 12 provided on the bottom of a reaction chamber 11. An upper electrode 13 is provided at the ceiling of the reaction chamber 11 to face the lower electrode 12 with a space in which plasma is to be generated interposed there between. An RF power supply 14 for applying power at 13.56 MHz to the lower electrode 12 is provided in the outside of the reaction chamber 11. A gas inlet 15 for introducing a process gas into the reaction chamber 11 and a gas outlet 16 for letting out the process gas from the reaction chamber 11 is each provided through the side wall of the reaction chamber 11. A focus ring mainly composed of silicon (Si focus ring) 17 is provided on the lower electrode 12 and surrounds the substrate 20.

Although not shown, a silicon oxide film as an object to be etched (hereinafter, referred to as an etching object) is formed over the substrate 20 with a silicon nitride film, for example, interposed there between.

FIG. 13 is a plan view showing a structure of the Si focus ring 17 shown in FIG. 12, i.e., a conventional focus ring. As shown in FIG. 13, the Si focus ring 17 is a single ring having, at its center, an opening whose diameter corresponds to the diameter of the substrate 20, i.e., wafer.

In the dry etching apparatus shown in FIG. 12, a member made of silicon is placed inside the reaction chamber 11, more specifically, the Si focus ring 17 is placed on the periphery of the lower electrode 12, so that the SiO₂/Si selectivity is enhanced. This is because of the following reasons. That is, in the reaction chamber 11, silicon constituting the Si focus ring 17 reacts with etching gas radicals, so that the etching gas radicals are scavenged and the density of the etching gas radicals decreases. Accordingly, the etching gas/the etchant ratio increases and thereby the etching rate of silicon decreases, thereby enhancing the SiO₂/Si selectivity. That is, the focus ring has a function of controlling the density of radicals or ions by reacting with the radicals or ions in the plasma (see, for example, Japanese Patent No. 3333177 (pp 11 to 12), Japanese Patent Laid-Open Publication No. 7-245292 (p2), Japanese Patent Laid-Open Publication No. 8-186096 (p2), Japanese Patent Laid-Open Publication No. 2002-9048 (FIG. 4), Japanese Patent Laid-Open Publication No. 2002-164323 (p3) and Japanese Patent Laid-Open Publication No. 2002-190466 (p2)).

In the past, oxide-film etching was mainly used for forming, for example, a contact hole in an oxide film. However, with recent progress of miniaturization found in ITRS (International Technology Roadmap for Semiconductor), the thickness of resists has been reduced, resulting in that hard masks made of oxide films or other materials have come to be adopted in conventional etching processes in which resist patterns are used as masks. As a typical example, a hard mask of an oxide film is used in an etching process for forming a gate electrode of polycrystalline silicon.

However, if the conventional dry etching apparatus shown in FIG. 12 is used in patterning the above-mentioned hard mask of the oxide film, the following problems arise.

FIGS. 14A and 14B are views for explaining problems in oxide-film etching using the conventional dry etching apparatus.

As shown in FIG. 14A, a resist pattern 22 having, for example, a gate electrode pattern is formed on an oxide film 21 as an etching object. This resist pattern 22 has a width L₀(critical dimension after lithography). Thereafter, as shown in FIG. 14B, the oxide film 21 is etched using the resist pattern 22 as a mask, thereby patterning the oxide film 21. The patterned oxide film 21A has a width L₁ (critical dimension after dry etching).

However, in the case of using the conventional dry etching apparatus, there arise a problem in which the oxide film 21 after etching (i.e., the patterned oxide film 21A in cross section) does not have a desired vertical shape but a tapered shape, as shown in FIG. 14B. There also arises another problem of an increased amount of a critical dimensional shift (critical dimension L₁ after dry etching—critical dimension L₀ after lithography).

### SUMMARY OF THE INVENTION

It is therefore an object of the present invention to allow an etching to be performed with the amount of the critical dimensional shift suppressed and a desired etched shape obtained, irrespective of a pattern to be formed. More specifically, an object of the present invention is to obtain a desired etched shape while suppressing the amount of the critical dimensional shift, irrespective of a pattern to be formed.

In order to achieve this object, the present inventor studied to find causes of increase in the amount of a critical dimensional shift and deterioration of controllability of an etched shape under following one of considerations.

Hereinafter, a method for performing etching on an oxide film using the conventional etching apparatus shown in FIG. 12 will be described specifically.

First, a fluorocarbon gas such as a C₄F₈, C₅ μg or CF₄ gas as a reactive gas is supplied to the reaction chamber 11 through the gas inlet 15, thereby generating plasma made of the gas. In this plasma, the following dissociation occurs:

C₄F₈→C₄F₇+F or

CₓF_{y+1}→CₓF_{y}+F

As a result, radicals (activated species) or ions of CₓF_{y} (where x and y are natural numbers) or F (fluorine) are supplied onto the substrate 20.

At this time, a reaction expressed by

SiO₂+F→SiFₓ+O* (Equation 1)

occurs between the oxide film (SiO₂ film) over the substrate 20 and, for example, fluorine radicals, so that etching of the oxide film (hereinafter, referred to as oxide-film etching) proceeds. In this manner, the oxide film is processed.

The fluorocarbon (CₓF_{y}) radicals generated from the plasma produces a polymer (fluorocarbon polymer) of carbon and fluorine over the oxide film as the object to be etched. However, a reaction expressed by

CₓF_{y}+O*→COₓ+F (Equation 2)

occurs between O* (oxygen radical) generated through the reaction expressed by Equation 1 and the fluorocarbon polymer, so that the fluorocarbon polymer on the oxide film is removed.

On the other hand, when the oxide-film etching is produced and the silicon substrate or the silicon nitride film under the oxide film are exposed, the generation of O* as shown in Equation 1 does not occur. Accordingly, the removal of the fluorocarbon polymer caused by the oxygen radicals as expressed by Equation 2 does not occur. That is, the fluorocarbon radicals cause the fluorocarbon polymer to be deposited on the silicon substrate or the silicon nitride film. As a result, the etching rate of silicon or the silicon nitride film decreases, thus securing the selectivity between the oxide film and its underlying silicon or silicon nitride film. The SiO₂/Si selectivity (or SiO₂/SiN selectivity) generally depends on the ratio of fluorocarbon radicals to fluorine radicals (hereinafter, referred to as a CₓF_{y}/F ratio) in the plasma in general. Specifically, as the_CₓF_{y}/F ratio increases, the etching rate of silicon decreases, so that the SiO₂/Si selectivity increases. In contrast, as the CₓF_{y}/F ratio decreases, the etching rate of silicon increases, so that the SiO₂/Si selectivity decreases. In this way, the control of the CₓF_{y}/F ratio is very important in oxide-film etching.

That is, in oxide-film etching for, for example, forming a contact hole for which the conventional etching apparatus has been used without problems, the opening area ratio of the oxide film as an object to be etched is about several percent at most. The opening area ratio is herein the ratio of the area of the oxide film to be removed by etching with respect to the entire area of the oxide film before etching. In other words, the opening area ratio is the ratio of the area of apertures in the oxide film per one chip with respect to the area of the chip.

On the other hand, in oxide-film etching for forming, for example, an oxide-film hard mask having a gate electrode pattern, which involves a problem if the conventional etching apparatus is used, the opening area ratio of the oxide film is as high as about 20 to 80%, which is much higher than the opening area ratio in conventional contact-hole formation.

The present inventor found out that the above problems occur when oxide-film etching with a high opening area ratio is performed using the conventional etching apparatus in which the CₓF_{y}/F ratio in the reaction chamber is enhanced by the shield comprised a Si focus ring for forming, for example, a contact hole. Specifically, in this case, the amount of fluorine radicals, i.e., an etchant (etching species), is insufficient for the area of the oxide film to be etched, whereas fluorocarbon radicals to be a cause of polymer deposition, i.e., deposition species, is in excess. As a result, an appropriate CₓF_{y}/F ratio is not obtained in the reaction camber, so that the amount of a critical dimensional shift increases and the controllability of the etched shape (hereinafter, referred to as shape controllability) deteriorates.

In addition, based on the foregoing findings, the present inventor came up with the idea of solving the above-described problems by adjusting the surface area of the shield of the etching apparatus in accordance with the opening area ratio of the object to be etched. Specifically, in the case of oxide-film etching, if the surface area of the shield composed of Si for scavenging fluorine radicals in a plasma is changed in accordance with the opening area ratio of an oxide film, the CₓF_{y}/F ratio over the oxide film is optimized, thus preventing increase in the amount of a critical dimensional shift and deterioration of the shape controllability.

Further, the present inventor also came up with the idea of forming a shield using Si that reacts with fluorine radicals in the plasma and also using a material (e.g., SiC, SiO₂, Al₂O₃ or Y₂O₃) having low reactivity with the fluorine radicals to control the amount of scavenged fluorine radicals at points on the shield and thereby improve the uniformity of the CₓF_{y}/F ratio in the wafer surface.

The present invention has been made based on the foregoing findings. Specifically, a first etching apparatus according to the present invention is based on an etching apparatus including a shield provided on an electrode in a reaction chamber and surrounding an object to be etched. In this first etching apparatus, the shield has a surface area according to an opening area ratio of the object to be etched.

With the first etching apparatus, the shield has a surface area according to the opening area ratio of the object to be etched, so that the amount of scavenged etchant such a fluorine radical in plasma is controlled in accordance with the opening area ratio of the object to be etched. Specifically, a shield having a surface area which decreases as the opening area ratio of the object to be etched (i.e., the area to be etched) increases is used, so that the amount of scavenged etchant such a fluorine radical is reduced. On the other hand, a shield having a surface area which increases as the opening area ratio of the object to be etched decreases is used, so that the amount of scavenged etchant such fluorine radical is increased. Accordingly, it is possible to perform the etching such that the amount of a critical dimensional shift is suppressed and a desired etched shape is obtained, irrespective of a pattern to be formed.

A second etching apparatus according to the present invention is based on an etching apparatus including a shield provided on an electrode in a reaction chamber and surrounding an object to be etched. In this second etching apparatus, the shield is constituted by one shield unit or a combination of two or more units selected from a plurality of units which have been prepared beforehand and have different radiuses such that the shield has a surface area according to an opening area ratio of the object to be etched.

With the second etching apparatus, the shield is constituted by one unit or a combination of two or more units selected from a plurality of units with different radiuses such that the unit has a surface area according to the opening area ratio of the object to be etched. That is, in the second etching apparatus, as in the first etching apparatus, the shield also has a surface area according to the opening area ratio of the object to be etched, so that the same effects as in the first etching apparatus are obtained. In addition, the surface area of the shield is adjusted easily.

The size of a shield herein is the length from the center to the outer periphery (outside shield) of the shied having a given width, except where specifically noted. The first and second etching apparatuses are based on the premise that the shield is provided on the electrode such that the inner side of the shield is in contact with the edge of the substrate (wafer) over which the object to be etched (e.g., an oxide film) is formed. In other words, the shield according to the present invention has an opening corresponding to the diameter of the wafer at its center. Accordingly, the surface area of the shield is herein the area of a portion of the shield exposed to plasma in the reaction chamber, i.e., the total area of the upper and outside surfaces of the shield surrounding the object to be etched.

In the second etching apparatus, the plurality of shield units constituting the shield is fit together with no gaps there between. Specifically, shield units are combined such that the outer side of a shield unit with a smaller size is in contact with the inner side of a shield unit with a larger size.

In the second etching apparatus, each of the plurality of shield units preferably contains silicon as a main component.

Then, in the case of oxide-film etching (i.e., in a case where the object to be etched is an oxide film), the surface area of the shield containing silicon as a main component is adjusted in accordance with the opening area ratio of the oxide film as the object to be etched. This allows the control of the amount of scavenged etchant for the oxide film (e.g., fluorine radicals in the plasma), thus optimizing the amount ratio (e.g., CₓF_{y}/F ratio) between the deposition species (e.g., CₓF_{y} radicals in the plasma) and the etchant on the oxide film. As a result, it is possible to obtain a desired etched shape while suppressing the amount of a critical dimensional shift during oxide-film etching, irrespective of a pattern to be formed, as intended.

In the second etching apparatus, the plurality of shield units preferably include at least two shield units whose main components differ from each other.

Then, the shield is constituted by a shield unit (or a plurality of shield units) containing a material exhibiting a high etchant scavenging ability as a main component and another shield unit (or a plurality of shield units) containing a material exhibiting a low etchant scavenging ability as a main component. With this structure, a sharp change in the amount of the etchant on the shield unit (i.e., on the periphery of the wafer) is suppressed, so that the uniformity in the wafer surface regarding, for example, the etching ratio of the object to be etched, the selectivity between the object to be etched and its underlying material or the etched shape is improved.

The phrase of “containing a material as a main component” herein includes “made of only one material”.

In the second etching apparatus, the plurality of shield units preferably includes a first shield unit containing silicon as a main component and a second shield unit containing a material other than silicon as a main component.

Then, in the case of oxide-film etching (i.e., in a case where the object to be etched is an oxide film), the shield is constituted by a first shield unit (or a plurality of shield units) containing a material exhibiting a high etchant (e.g., fluorine radicals) scavenging ability as a main component and a second shield unit (or a plurality of shield units) containing a material exhibiting a low etchant scavenging ability as a main component. With this structure, a sharp change in the amount of the etchant on the shield (i.e., on the periphery of the wafer) is suppressed and thus the amount ratio (e.g., CₓF_{y}/F ratio) between the deposition species (e.g., CₓF_{y} radicals) and the etchant is also suppressed. Accordingly, the uniformity in the wafer surface regarding, for example, the etching ratio of the oxide film, the selectivity between the oxide film and its underlying material or the etched shape is improved. If said material other than silicon contains at least one material selected from the group consisting of quartz (SiO₂), silicon carbide (SiC), aluminum oxide (Al₂O₃) and yttrium oxide (Y₂O₃), the improvement of the uniformity in the wafer surface regarding, for example, the etching ratio is ensured.

In the second etching apparatus, the plurality of shield units preferably includes at least a shield unit containing, as a main component, the same material as the object to be etched.

Then, in the case of etching of, for example, an oxide film (a SiO₂ film), if a shield including a shield of SiO₂ is used, the area to be etched (SiO₂ area), i.e., the opening area ratio, is increased in effect. In other words, if a shield is formed using a ring containing the same material as the object to be etched as a main component, the area to be etched is substantially increased. In this manner, the amount of an etchant supplied onto a portion to be etched (under an opening of a resist mask) on an object to be etched having an opening area ratio of, for example, about several percent is adjusted to substantially the same amount as an etchant supplied to a portion to be etched on an object to be etched having an opening area ratio of, for example, about several tens percent. That is, only by adjusting the structure of the shield, etching can be performed with high accuracy on etching objects having various opening area ratios using the same etching apparatus.

An etching method according to the present invention is based on an etching method using an etching apparatus including a shield which is provided on an electrode in a reaction chamber and surrounds an object to be etched. The method includes the steps of: mounting the object to be etched on the electrode; introducing a gas into the reaction chamber to generate a plasma of the gas and performing etching on the object to be etched by using the plasma; and adjusting the surface area of the shied in accordance with an opening area ratio of the object to be etched, before the step of performing etching.

With the inventive etching method, in performing etching, the surface area of the shield is adjusted in accordance with the opening area ratio of the object to be etched, so that the amount of scavenged etchant in plasma is controlled in accordance with the opening area ratio of the object to be etched. Specifically, the surface area of the shield is reduced as the opening area ratio of the object to be etched (i.e., the area to be etched) increases, so that the amount of scavenged etchant is reduced. On the other hand, the surface area of the shield is increased as the opening area ratio of the object to be etched decreases, so that the amount of scavenged etchant is increased. Accordingly, it is possible to perform etching such that the amount of a critical dimensional shift is suppressed and a desired etched shape is obtained, irrespective of a pattern to be formed.

In the inventive etching method, the step of adjusting the surface area of the shield preferably includes the step of selecting one shield unit or a combination of two or more shield units from a plurality of shield units which have been prepared beforehand and have different size and forming the shield by the selected shield unit or the combination of shield units.

Then, the surface area of the shield unit is adjusted easily.

In this case, the plurality of shield units preferably includes at least two shield units whose main components differ from each other.

Then, the shield is constituted by a shield (or a plurality of shield units) containing a material exhibiting a high etchant scavenging ability as a main component and another shield unit (or a plurality of shield units) containing a material exhibiting a low etchant scavenging ability as a main component. With this configuration, a sharp change in the amount of an etchant on the shield (i.e., on the periphery of the wafer) is suppressed, so that the uniformity in the wafer surface regarding, for example, the etching ratio of the object to be etched, the selectivity between the object to be etched and its underlying material or the etched shape is improved.

In the inventive etching method, the gas preferably contains at least one gas selected from the group consisting of CF₄, CHF₃, C₄F₈, C₅F₈, C₄F₆ and C₂F₆.

Then, in the case of oxide-film etching (i.e., in a case where the object to be etched is an oxide film), if the surface area of the shield containing silicon as a main component is adjusted in accordance with the opening area ratio of the oxide film, the amount of scavenged etchant for the oxide film (e.g., fluorine radicals in the plasma) is controlled. Accordingly, the amount ratio (e.g., CₓF_{y}/F ratio) between the deposition species (e.g., CₓF_{y} radicals in the plasma) and the etchant on the oxide film is optimized, thus ensuring a desired etched shape, while suppressing the amount of a critical dimensional shift during oxide-film etching, irrespective of a pattern to be formed.

As described above, according to the present invention, a shield is constituted by a combination of shield units selected from a plurality of shield units with different size, so that the surface area of the shield is adjusted in accordance with the opening area ratio of an object to be etched. That is, if the opening area ratio is high, the surface area of the shield is reduced so that the amount of scavenged etchant decreases. On the other hand, if the opening area ratio is low, the surface area of the shield is increased so that the amount of scavenged etchant increases. Accordingly, it is possible to perform etching such that the amount of a critical dimensional shift is suppressed and a desired etched shape is obtained, irrespective of a pattern to be formed.

The present invention relates to etching apparatus and etching methods. The present invention is effective especially when applied to oxide-film etching for forming a hard mask or a trench.

### BRIEF DESCRIPTION OF THE DRAWINGS

FIG. 1 is a view schematically showing a structure of an etching apparatus according to a first embodiment of the present invention.

FIG. 2 is a plan view showing a structure of a focus ring in the etching apparatus of the first embodiment.

FIG. 3 is a graph showing a result obtained by the present inventor regarding how a CₓF_{y}/F ratio varies when the radius of a Si focus ring is changed under the same etching conditions as in an etching method according to the first embodiment.

FIG. 4A is a view showing a case where an oxide film as an etching object is patterned into an inverted tapered shape. FIG. 4B is a view showing a case where an oxide film as an etching object is patterned into a vertical shape. FIG. 4C a view showing a case where an oxide film as an etching object is patterned into a tapered shape.

FIG. 5 is a graph showing a result obtained by the present inventor regarding a relationship between an opening area ratio of an oxide film and the radius of a Si focus ring allowing the etched shape of the oxide film to be a vertical shape under the same etching conditions as in the etching method of the first embodiment.

FIGS. 6A through 6C are cross-sectional views showing respective process steps of a method for forming a trench utilizing the apparatus and method for dry etching of the first embodiment.

FIGS. 7A through 7C are cross-sectional views showing respective process steps of a method for forming a trench according to a comparative example.

FIG. 8 is a cross-sectional view showing one of the process steps of the method for forming a trench according to the comparative example.

FIG. 9 is a view schematically showing a structure of a dry etching apparatus according to a second embodiment of the present invention.

FIG. 10 is a plan view showing a structure of a focus ring in the dry etching apparatus of the second embodiment.

FIG. 11A is a graph showing a result obtained by the present inventor regarding a distribution of a CₓF_{y}/F ratio in a direction of the wafer radius in a case of using a Si focus ring under the same etching conditions as in a dry etching method according to the second embodiment. FIG. 11B a graph showing a result obtained by the present inventor regarding a distribution of a CₓF_{y}/F ratio in a direction of the wafer radius in a case of using a focus ring constituted by a SiC ring and a Si ring under the same etching conditions as in the dry etching method of the second embodiment.

FIG. 12 is a view schematically showing a structure of a conventional dry etching apparatus.

FIG. 13 is a plan view showing a structure of a focus ring in the conventional dry etching apparatus.

FIGS. 14A and 14B are views for explaining problems in oxide-film etching using the conventional dry etching apparatus.

### DESCRIPTION OF THE PREFERRED EMBODIMENTS

Embodiment 1

Hereinafter, a etching apparatus and a etching method according to a first embodiment of the present invention will be described with reference to the drawings, taking oxide-film etching as an example.

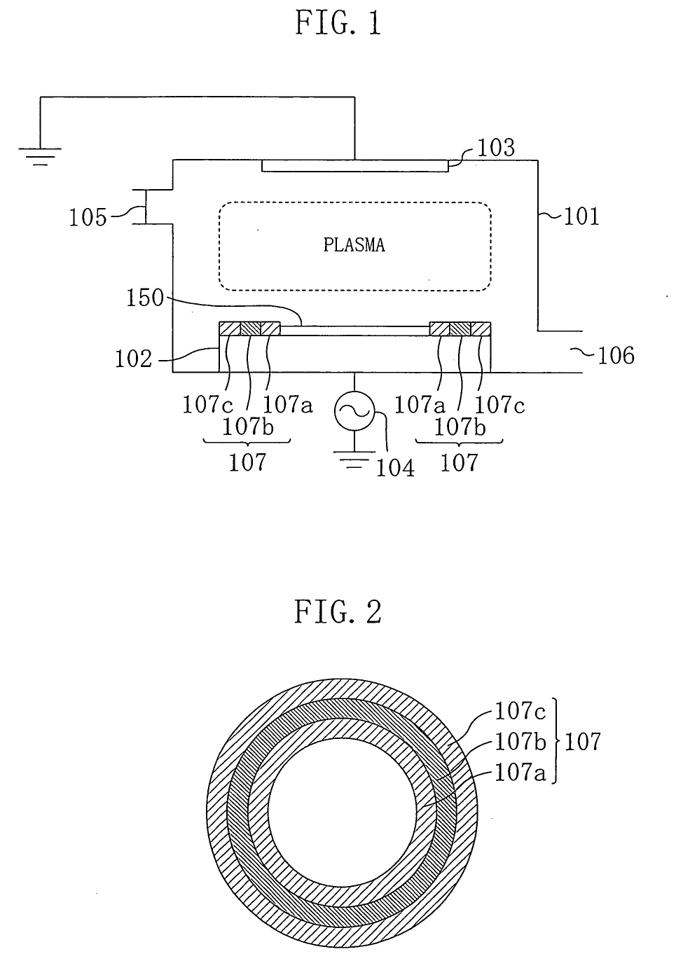

FIG. 1 schematically shows a structure of the etching apparatus according to the first embodiment.

As shown in FIG. 1, a substrate 150 to be processed is mounted on a lower electrode 102 provided on the bottom of a reaction chamber 101. An upper electrode 103 is placed on the ceiling of the reaction chamber 101 to face the lower electrode 102 with a space in which plasma is to be generated interposed there between. An RF power supply 104 for applying power at, for example, 13.56 MHz to the lower electrode 102 is provided in the outside of the reaction chamber 101. A gas inlet 105 for introducing a process gas into the reaction chamber 101 and a gas outlet 106 for letting out the process gas from the reaction chamber 101 is each provided through the wall of the reaction chamber 101. A shield such as a focus ring 107 is provided on the lower electrode 102 to surround the substrate 150.

Although not shown, a silicon oxide film as an object to be etched is formed over the substrate 150 with a silicon nitride film, for example, interposed there between.

FIG. 2 is a plan view showing a structure of the shield comprised of the focus ring 107 shown in FIG. 1, i.e., a focus ring according to this embodiment.

As shown in FIG. 2, the shield such as the focus ring 107 of this embodiment is characterized by being constituted by a plurality of rings which have different radiuses and are arranged concentrically. Specifically, FIG. 2 shows that a first shield unit such as a first ring 107a with a width of 2 cm and an outside radius of 12 cm, a second shield unit such as a second ring 107b with a width of 2 cm and an outside radius of 14 cm and a third shield such as a third ring 107c with a width of 2 cm and an outside radius of 16 cm are fit together with no gaps there between to form the shield such as the focus ring 107. In this case, the inner side of the first ring 107a serving as the inner side of the focus ring 107 is in contact with the edge of the wafer with a radius of 10 cm as the substrate 150. In this embodiment, each of the rings 107a, 107b and 107c contains silicon as a main component.

In the case shown in FIG. 2, the combination of the three rings 107a through 107c forms the focus ring 107 with a width of 6 cm and a radius (outside radius) of 16 cm.

However, in this embodiment, the combination of the rings may be varied so as to arbitrarily change the width and radius of the focus ring 107, i.e., the surface area of the focus ring 107. For example, the first ring 107a and the second ring 107b may be combined to form a focus ring 107 with a width of 4 cm and a radius of 14 cm.

In this embodiment, the surface area of the focus ring 107 is the area of a portion of the focus ring 107 exposed to the plasma in the reaction chamber 101, i.e., the total area of the upper and outside surfaces of the focus ring 107 surrounding the substrate (wafer) 150.

Hereinafter, a method for dry etching an oxide film using the dry etching apparatus of this embodiment shown in FIG. 1 will be described specifically.

First, a fluorocarbon gas (reactive gas) such as a C₄F₈, C₅F₈ or CF₄ gas, an Ar gas and an oxygen gas are supplied to the reaction chamber 101 through the gas inlet 105, thereby generating a plasma made of these gases. An oxide film over the substrate 150 is then etched using the plasma. Specific etching conditions in this case are: the flow rate of, for example, C₄F₈ is 10 ml/min (under standard conditions); the O₂ flow rate is 5 ml/min (under standard conditions); the Ar flow rate is 400 ml/min (under standard conditions); the pressure in the chamber is 7 Pa; the RF power for plasma generation is 1500 W; and the substrate temperature is 20° C.

In the above-mentioned plasma, the gasses introduced into the reaction chamber 101 are dissociated, thereby generating CₓF_{y} radicals (fluorocarbon radicals) to act as a deposition species and F radicals (fluorine radicals) to act as an etchant. These fluorine radicals react with silicon contained in the focus ring 107 and are scavenged, so that the fluorine radicals in the plasma decrease substantially. Since this decrease of the fluorine radicals is caused by the reaction between the focus ring 107 and the fluorine radicals, the fluorine radicals decreases in proportion to the surface area of the focus ring 107. Accordingly, the amount ratio of the deposition species and the etchant (i.e., CₓF_{y}/F ratio) also increases in proportion to the surface area of the focus ring 107.

On the other hand, in this embodiment, it is possible to change the surface area of the focus ring 107 by changing the radius (outside radius) of the focus ring 107 using various combinations of a plurality of rings, thereby changing the CₓF_{y}/F ratio in the plasma, as described above.

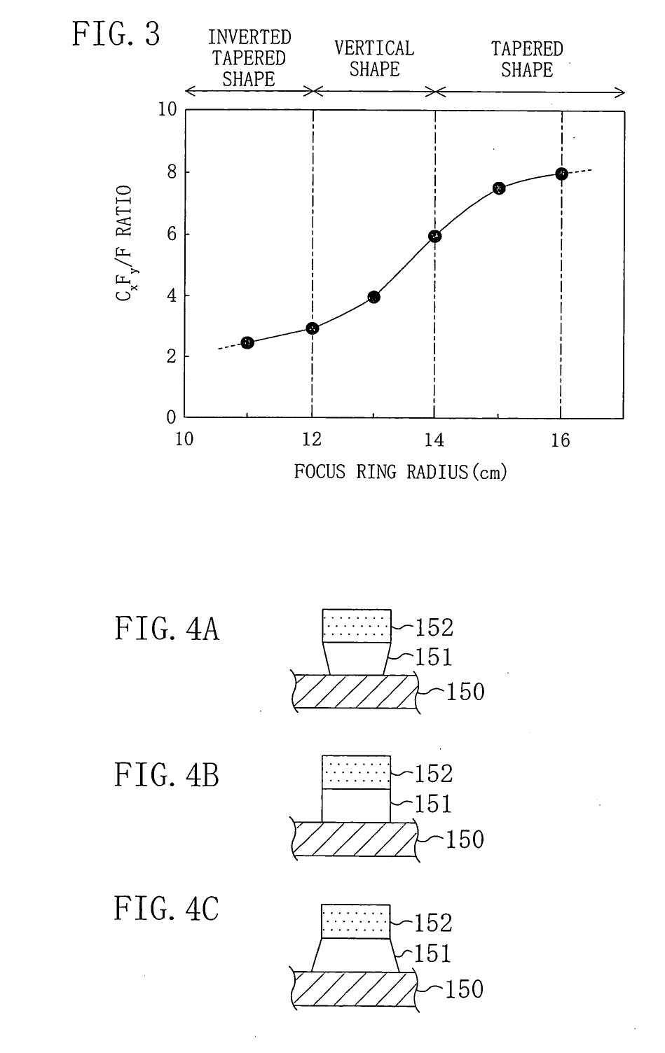

FIG. 3 shows how the CₓF_{y}/F ratio varies when the radius of a Si focus ring is changed under the same etching conditions as in this embodiment. In FIG. 3, the abscissa represents the radius (outside radius) of the focus ring and the ordinate represents the CₓF_{y}/F ratio. The CₓF_{y}/F ratio shown in FIG. 3 is obtained at the center of a wafer (substrate to be processed) with a radius of 10 cm in a case where the opening area ratio of an oxide film as an etching object is 80%. In a case where the substrate to be processed is a wafer with a radius of 10 cm, the radius of the focus ring is always greater than 10 cm.

As shown in FIG. 3, as the radius of the Si focus ring increases, the amount of scavenged fluorine radicals increases, so that the CₓF_{y}/F ratio increases. In this case, a Si focus ring with a radius of 12 cm is formed only by the first ring 107a of this embodiment, for example. A Si focus ring with a radius of 14 cm is formed by a combination of the first and second rings 107a and 107b of this embodiment, for example. A Si focus ring with a radius of 16 cm is formed by a combination of the first, second and third rings 107a, 107b and 107c of this embodiment, for example.

FIG. 3 also shows a relationship between the radius of the Si focus ring and the etched shape of the oxide film in a case where the oxide film is patterned into a line to have an opening area ratio of 80%. As shown in FIG. 3, as the radius of the focus ring increases, the etched shape of the line pattern formed out of the oxide film changes from an inverted tapered shape to a vertical shape and then to a tapered shape. This phenomenon occurs because fluorine radicals to act as an etchant for the oxide film decrease with the increase of the radius of the focus ring. That is, the etched shape of the oxide film changes depending on the radius of the Si focus ring. Under the same etching conditions as in this embodiment, a vertical shape, which is an excellent etched shape, is obtained in the range in which the radius of the Si focus ring is from 12 cm to 14 cm.

FIG. 4A shows a case where the oxide film 151 over the substrate 150 is patterned into an inverted tapered shape under conditions in which dry etching is performed on the oxide film 151 using the resist pattern 152 as a mask. FIG. 4B shows a case where the oxide film 151 is patterned into a vertical shape under the same condition. FIG. 4C shows a case where the oxide film 151 is patterned into a tapered shape under the same conditions.

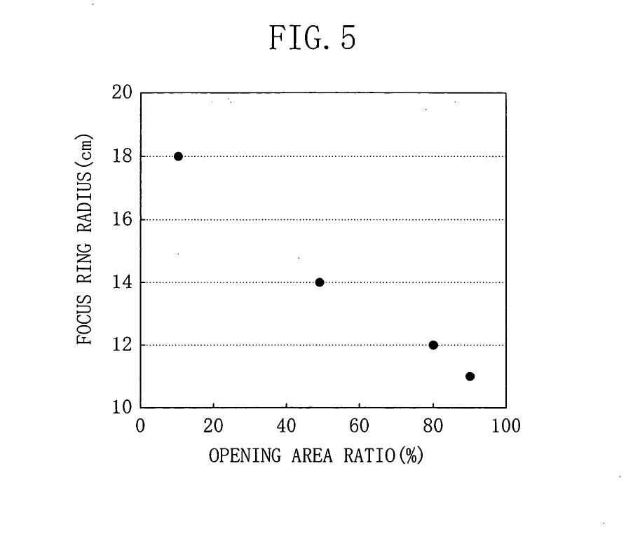

FIG. 5 shows a relationship between an opening area ratio of an oxide film as an etching object and a radius of a Si focus ring allowing the etched shape of the oxide film to be a vertical shape. In FIG. 5, the abscissa represents the opening area ratio and the ordinate represents the radius (outside radius) of the focus ring. The relationship shown in FIG. 5 was obtained under the same etching conditions as in this embodiment.

As shown in FIG. 5, to achieve a vertical etched shape of the oxide film, the radius of the focus ring needs to be reduced as the opening area ratio increases. This is because of the following reasons. That is, as the opening area ratio increases, i.e., the area of the oxide film to be etched increases, a larger amount of etchant (fluorine radicals) is required during etching. Accordingly, to suppress the amount of scavenged fluorine radicals, the radius of the Si focus ring needs to be reduced. In contrast, as the opening area ratio decreases, i.e., the area of the oxide film to be etched decreases, a smaller amount of fluorine radicals is required during etching. Accordingly, to increase the amount of scavenged fluorine radicals, the radius of the focus ring needs to be increased.

As described above, in this embodiment, it is possible to set the radius (outside radius) of the focus ring 107 at an appropriate value by varying the combination of a plurality of rings. For example, if the focus ring 107 is constituted only by the first ring 107a with the minimum radius, the surface area of the focus ring 107 is small so that the amount of scavenged (decreased) fluorine radicals is suppressed and the CₓF_{y}/F ratio decreases. Therefore, this structure is suitable for high opening area ratios. On the other hand, if the focus ring 107 is constituted by the combination of all the three rings 107a through 107c, the surface area of the focus ring 107 increases so that the amount of scavenged (decreased) fluorine radicals increases and the CₓF_{y}/F ratio increases. Therefore, this structure is suitable for low opening area ratios.

As described above, in the first embodiment, the focus ring 107 is constituted by a combination of rings which are selected from a plurality of rings with different radiuses in such a manner that allows the focus ring 107 to have a surface area according to the opening area ratio of the etching object. Accordingly, the radius and the surface area of the focus ring 107 are adjusted easily in accordance with the opening area ratio of the etching object. Specifically, if the surface area of the focus ring 107 is adjusted by varying the combination of a plurality of rings each containing silicon as a main component in accordance with the opening area ratio of the oxide film as an etching object, it is possible to control the amount of scavenged fluorine radicals acting as an etchant for the oxide film. Accordingly, the amount ratio of a deposition species (fluorocarbon radicals) to the etchant (i.e., the CₓF_{y}/F ratio) on the oxide film is optimized, so that it is possible to achieve a desired etched shape while suppressing a critical dimensional shift during the oxide-film etching, irrespective of a pattern to be formed.

In addition, in the first embodiment, even in a case where the opening area ratio of the oxide film exceeds 80%, if the radius of the focus ring 107 is reduced and the amount of scavenged fluoride radicals is suppressed so that the CₓF_{y}/F ratio is reduced, a vertical shape as a desired etched shape is achieved. For example, from the results shown in FIGS. 3 and 5, in a case where the opening area ratio of the oxide film is 80% and the same etching conditions as in this embodiment are adopted, if the third ring 107c is removed from the focus ring 107 shown in FIG. 2, an excellent etched shape is obtained. In other words, if a focus ring 107 with a radius of 14 cm constituted by a combination of the first and second rings 107a and 107b is used, an excellent etched shape is obtained.

In the first embodiment, the surface area of the focus ring 107 is adjusted by varying the combination of the three rings 107a through 107c with radiuses of 12 cm, 14 cm and 16 cm, respectively. However, in the first embodiment, the number and radiuses of rings for use in adjustment of the surface area of the focus ring 107 are not specifically limited. It should be noted that the rings constituting the focus ring 107 are fit together with no gaps there between and the focus ring 107 has, at its center, an opening whose diameter corresponds to the diameter of the wafer (substrate 150). Specifically, rings are combined such that the outer side of a ring with a smaller radius is in contact with the inner side of a ring with a larger radius, and the focus ring 107 is provided on the lower electrode 102 such that the inner side of the focus ring 107 is in contact with the edge of the substrate 150. In the first embodiment, the focus ring 107 may be constituted by a single ring with the most appropriate radius according to the opening area ratio of the oxide film.

In the first embodiment, silicon is used as a main component of each of the rings constituting the focus ring 107 in order to control the amount of the scavenged etchant (fluorine radicals) in the plasma during oxide-film etching. However, even if the etching object is not an oxide film, materials appropriate for controlling the amount of the scavenged etchant for the etching object may be used as main components of the rings constituting the focus ring. In such a case, the same effects as in this embodiment are, of course, obtained.

In the first embodiment, C₄F₈ is used as a reactive gas (gas for plasma generation) for oxide-film etching. However, in this embodiment, the type of the gas for plasma generation is not limited and may be a gas containing at least one of CF₄, CHF₃, C₄F₈, C₅F₈, C₄F₆ and C₂F₆.

In the first embodiment, the focus ring 107 is mounted on the lower electrode 102 of the dry etching apparatus including the lower and upper electrodes 102 and 103 and surrounds the substrate 150. The type of the dry etching apparatus to which the present invention is applied is not limited. Specifically, the focus ring of the present invention may be mounted on an electrode in a reaction chamber of an etching apparatus of an ECR (electron cyclotron resonance) type or an ICP (inductively coupled plasma) type, for example, which does not include an upper electrode (but has an antenna and a coil). Even in such a case, the same effects as in this embodiment are obtained. In any type of the dry etching apparatus, the etching object such as a wafer may be, of course, mounted on an electrode with a support such as a pedestal interposed there between.

The dry etching apparatus and method of the first embodiment are not specifically limited in application, but are effective especially when applied to oxide-film etching for forming a hard mask or a trench for, for example, interconnection.

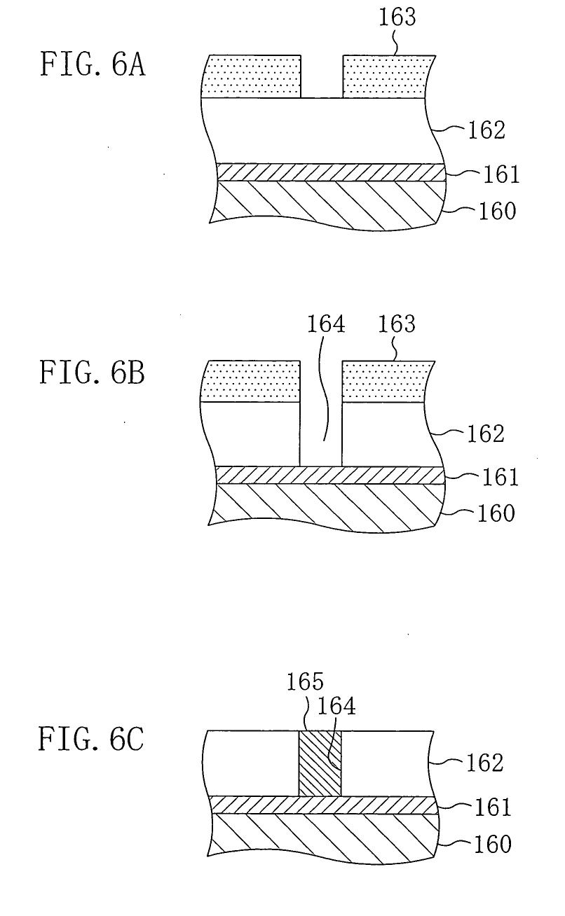

FIGS. 6A through 6C are cross-sectional views showing respective process steps of a method for forming a trench utilizing the apparatus and method for dry etching of the first embodiment.

First, as shown in FIG. 6A, an underlying film 161 of, for example, a SiC film or a SiN film and an oxide film 162 of, for example, an SiO₂ film are formed in this order over a substrate 160 of, for example, silicon. Thereafter, a resist pattern 163 having an opening at a trench region is formed on the oxide film 162 with a publicly-known lithography technique. In this case, the oxide film 162 as an etching object has an opening area ratio of about 30 to 70%. Next, as shown in FIG. 6B, the oxide film 162 is etched using the resist pattern 163 as a mask, thereby forming a trench 164. In this case, the dry etching apparatus of this embodiment shown in FIG. 1 is used and the surface area of the focus ring 107 (see FIG. 2) is adjusted in accordance with the opening area ratio of the oxide film 162. Specifically, the radius (outside radius) of the focus ring 107 is changed by varying the combination of a plurality of rings. In this manner, the amount of the scavenged etchant in a plasma generated in the reaction chamber 101 of the dry etching apparatus is controlled in accordance with the opening area ratio of the oxide film 162, so that the oxide film 162 is patterned into a vertical shape. That is, the trench 164 with a desired shape and without a critical dimensional shift is formed.

Then, as shown in FIG. 6C, the resist pattern 163 is removed, and then the trench 164 is filled with, for example, a barrier film and a copper film with a plating technique and a CMP (chemical mechanical polishing) process, for example, thereby forming an interconnect 165. In this case, the trench 164 has a desired shape without a critical dimensional shift, so that the interconnect 165 has desired electric characteristics.

### COMPARATIVE EXAMPLE

Hereinafter, as a comparative example, trench formation using a conventional dry etching apparatus and a conventional dry etching method will be described with reference to the drawings.

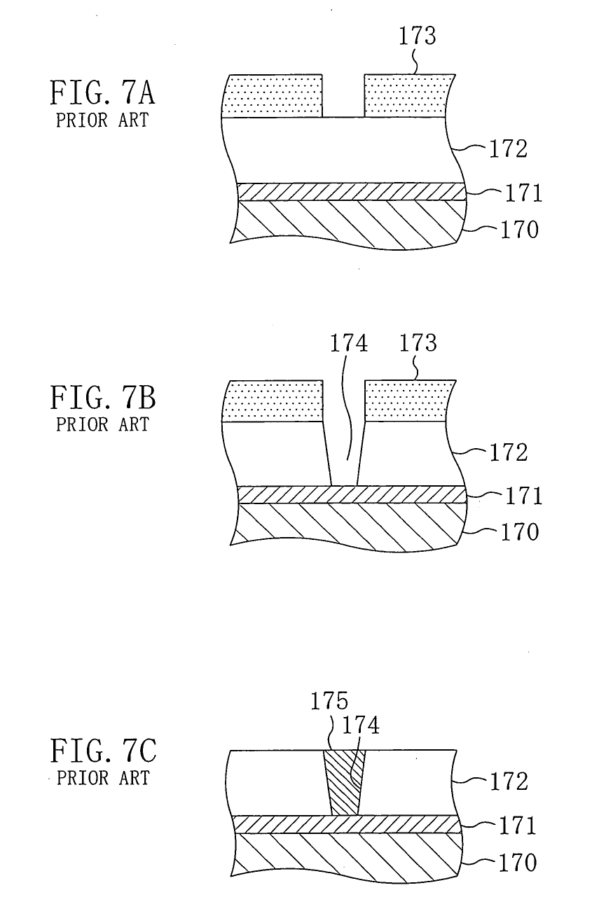

FIGS. 7A through 7C are cross-sectional views showing respective process steps of a method for forming a trench according to the comparative example.

First, as shown in FIG. 7A, an underlying film 171 of, for example, a SiC film or a SiN film and an oxide film 172 of, for example, an SiO₂ film are formed in this order over a substrate 170 of silicon. Thereafter, a resist pattern 173 having an opening at a trench region is formed on the oxide film 172 with a publicly-known lithography technique. In this case, the oxide film 172 as an etching object has an opening area ratio of about 30 to 70%.

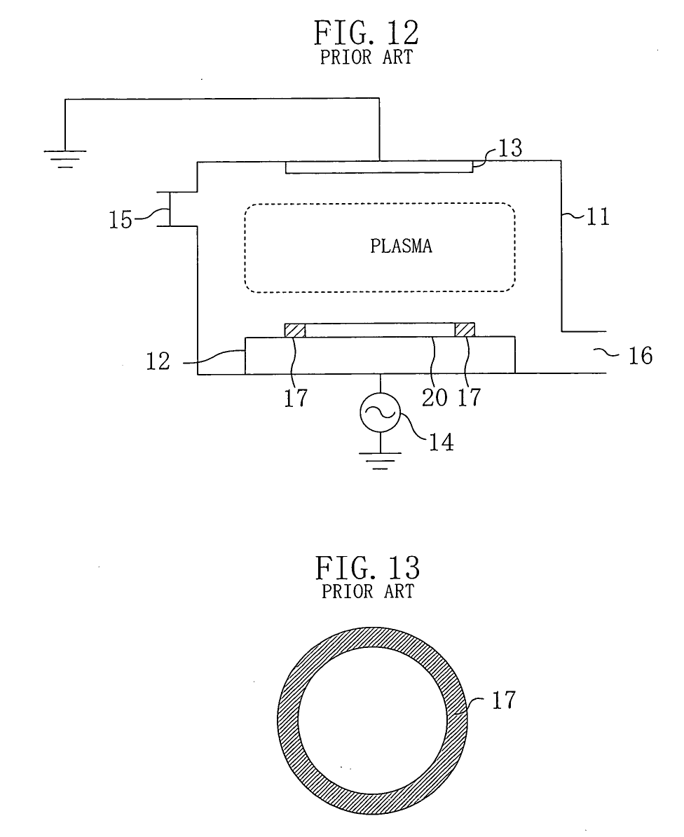

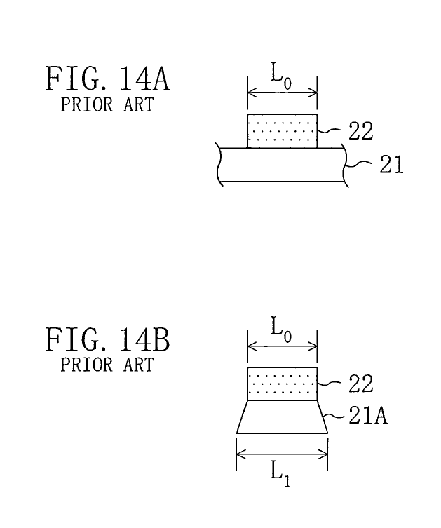

Next, as shown in FIG. 7B, the oxide film 172 is etched using the resist pattern 173 as a mask, thereby forming a trench 174. In this case, however, a conventional dry etching apparatus as shown in, for example, FIG. 12, i.e., a dry etching apparatus with a focus ring 17 (see FIG. 13) for forming a contact hole with an oxide film as an etching object having an opening area ratio of about several percent, is used, so that the etched shape of the oxide film 172 is not a desired vertical shape but a tapered shape. Specifically, the width of the resultant trench 174 narrows toward the bottom.

Thereafter, as shown in FIG. 7C, the resist pattern 173 is removed, and then the trench 174 is filled with a barrier film and a copper film with a plating technique and a CMP process, for example, thereby forming an interconnect 175. However, the interconnect 175 does not have a desired shape depending on the shape of the trench 174, so that the interconnect 175 has poor electric characteristics, e.g., high resistance.

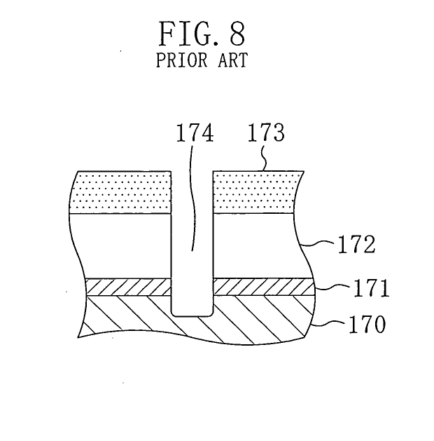

In the etching process shown in FIG. 7B, the flow rate of an O₂ gas in a process gas (e.g., a mixed gas of a reactive gas such as C₄F₈ or CHF₃, an Ar gas and an O₂ gas) to be introduced into a reaction chamber is increased, the reaction chamber is kept under a high degree of vacuum, or RF power for plasma generation (i.e., the ionization energy of an etchant) is increased, so that the oxide film 172 is patterned into a vertical shape. In this case, however, the selectivity between the oxide film 172 and the underlying film 171 (an etching stopper made of, for example, a SiC film or a SiN film) decreases, thus causing another problem that the etching reaches the underlying film 171 and the surface of the substrate 170 as shown in FIG. 8. On the other hand, in a case where the underlying film 171 is thick, another problem that the entire insulating film has a high effective dielectric constant arises because the relative dielectric constant of the underlying film 171 is about 5 to 7. This problem is noticeable especially in a case where a low-κ film having a relative dielectric constant of 3 or less is used instead of the oxide film 172.

Embodiment 2

Hereinafter, a dry etching apparatus and a dry etching method according to a second embodiment of the present invention will be described with reference to the drawings, taking an oxide-film etching as an example.

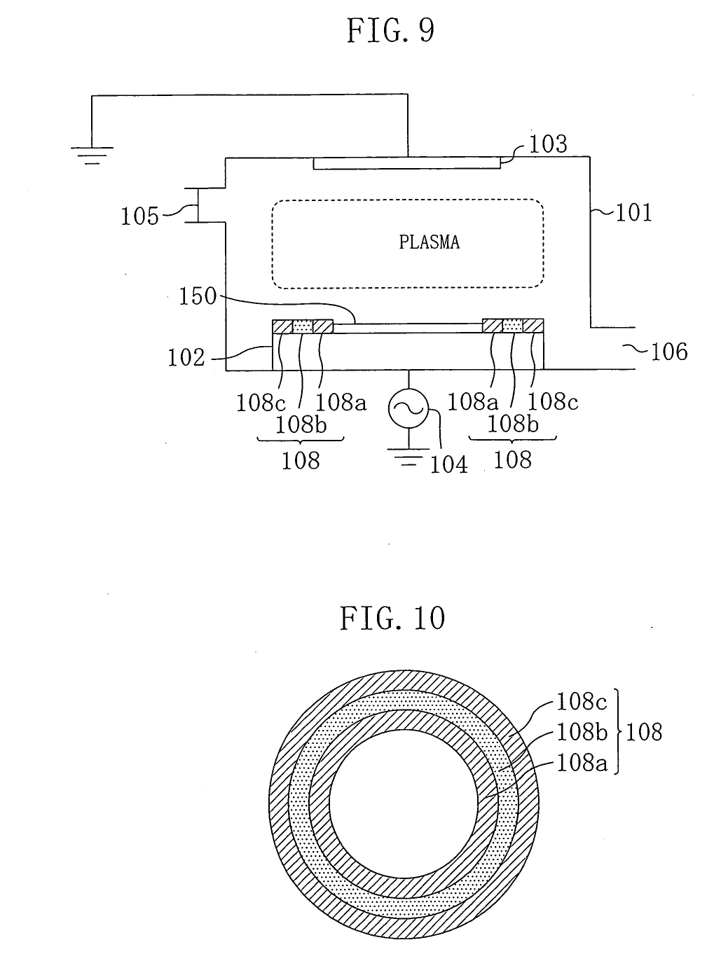

FIG. 9 schematically shows a structure of the dry etching apparatus of the second embodiment. In FIG. 9, each member already described for the dry etching apparatus of the first embodiment is identified by the same reference numeral and the description thereof will be omitted herein.

The second embodiment is different from the first embodiment in the structure of the focus ring 108 disposed on a lower electrode 102 and surrounding a substrate 150 to be processed.

Although not shown, in this embodiment, a silicon oxide film as an etching object is also formed over the substrate 150 with, for example, a silicon nitride film interposed there between.

FIG. 10 is a plan view showing the structure of the focus ring 108 shown in FIG. 9, i.e., a focus ring according to this embodiment.

As shown in FIG. 10, the focus ring 108 of this embodiment is characterized by being constituted by a plurality of rings which have different radiuses and are arranged concentrically, as in the first embodiment. Specifically, FIG. 10 shows that a first ring 108a with a width of 2 cm and an outside radius of 12 cm, a second ring 108b with a width of 2 cm and an outside radius of 14 cm, a third ring 108c with a width of 2 cm and an outside radius of 16 cm are fit together with no gaps there between to form the focus ring 108. In this case, the inner side of the first ring 108a serving as the inner side of the focus ring 108 is in contact with the edge of the wafer with a diameter of 10 cm as the substrate 150.

The first and third rings 108a and 108c contain silicon as main components as in the first embodiment, whereas the second ring 108b contains silicon carbide (SiC) as a main component unlike the first embodiment.

In a case shown in FIG. 10, the combination of the three rings 108a through 108c constitutes the focus ring 108 with a width of 6 cm and a radius (outside radius) of 16 cm. In this embodiment, the width and radius of the focus ring 108, i.e., the surface area of the focus ring 108, can be set at arbitrary values by varying the combination of rings. For example, if the first ring 108a and the second ring 108b are combined, a focus ring 108 having a width of 4 cm and a radius of 14 cm is formed.

In this embodiment, the surface area of the focus ring 108 is the area of a portion of the focus ring 108 exposed to a plasma in a reaction chamber 101, i.e., the total area of the upper and outside surfaces of the focus ring 108 surrounding the substrate (wafer) 150.

Hereinafter, a method for dry etching an oxide film using the dry etching apparatus of this embodiment shown in FIG. 9 will be described specifically.

First, a fluorocarbon gas (reactive gas) such as a C₄F₈, C₅F₈ or CF₄ gas, an Ar gas and an oxygen gas are supplied to the reaction chamber 101 through a gas inlet 105, thereby generating a plasma made of these gases. Then, an oxide film formed on the substrate 150 is etched using the plasma. Specific etching conditions in this case are: the flow rate of, for example, C₄F₈ is 10 ml/min (under standard conditions); the O₂ flow rate is 5 ml/min (under standard conditions); the Ar flow rate is 400 ml/min (under standard conditions); the pressure in the chamber is 7 Pa; the RF power for plasma generation is 1500 W; and the substrate temperature is 20° C.

In the above-mentioned plasma, the gasses introduced into the reaction chamber 101 are dissociated, thereby generating CₓF_{y} radicals (fluorocarbon radicals) to act as a deposition species and F radicals (fluorine radicals) to act as an etchant. These fluorine radicals react with silicon contained in the focus ring 108 and are scavenged, so that the fluorine radicals in the plasma decrease substantially. Since this decrease of the fluorine radicals is caused by the reaction between the focus ring 108 and the fluorine radicals, the fluorine radicals decreases in proportion to the surface area of the focus ring 108. Accordingly, the amount ratio of the deposition species and the etchant (i.e., CₓF_{y}/F ratio) also increases in proportion to the surface area of the focus ring 108. The reactivity of each of the first and third rings 108a and 108c containing silicon as main components with respect to the fluorine radicals is higher than that of the second ring 108b containing SiC as a main component.

On the other hand, in this embodiment, as described above, if the radius (outside radius) of the focus ring 108 is changed by varying the combination of the plurality of rings, the surface area of the focus ring 108 is adjusted, thereby changing the CₓF_{y}/F ratio in the plasma.

That is, in the second embodiment, the focus ring 108 is formed by combining rings which are selected from a plurality of rings with different radiuses in such a manner that allows the focus ring 108 to have a surface area according to the opening area ratio of the etching object. Accordingly, the radius and surface area of the focus ring 108 can be adjusted in accordance with the opening area ratio of the etching object. Specifically, if the surface area of the focus ring 108 is adjusted by varying the combination of a plurality of rings each containing silicon as a main component in accordance with the opening area ratio of the oxide film as an etching object, it is possible to control the amount of scavenged fluorine radicals as an etchant for the oxide film. Therefore, the amount ratio between the deposition species (fluorocarbon radicals) and the etchant (i.e., the CₓF_{y}/F ratio) on the oxide film is optimized, so that it is possible to obtain a desired etched shape while suppressing the amount of a critical dimensional shift during the oxide-film etching, irrespective of a pattern to be formed.

In addition, in the second embodiment, the focus ring 108 is constituted by a combination of a plurality of rings containing different materials as main components. Specifically, the focus ring 108 includes at least a first ring 108a containing, as a main component, silicon showing a high fluorine-radical scavenging ability and the second ring 108b containing, as a main component, SiC showing a low fluorine-radical scavenging ability. Accordingly, a sharp change in the fluorine radicals density distribution on the focus ring 108 (i.e., on the periphery of the wafer as the substrate 150) is suppressed, so that the uniformity in the wafer surface regarding, for example, the etching rate of the oxide film, the selectivity between the oxide film and its underlying material or the etched shape is improved. Hereinafter, effects of this embodiment will be described in detail:

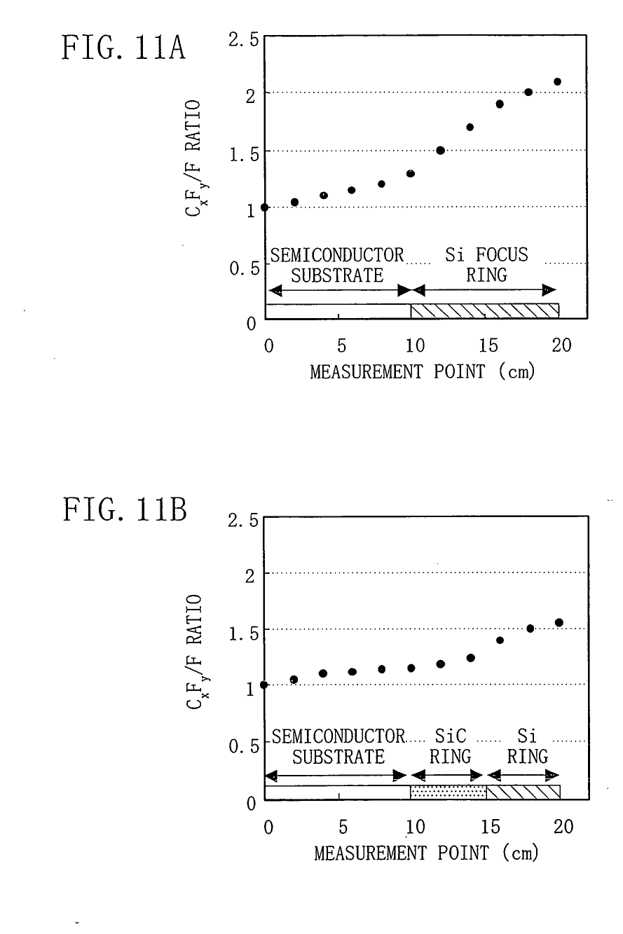

FIG. 11A shows, as a comparative example, a distribution of the CₓF_{y}/F ratio in a direction of the wafer radius in a case of using a Si focus ring with a width of 10 cm and a radius (outside radius) of 20 cm under etching conditions of this embodiment. FIG. 11B shows a distribution of the CₓF_{y}/F ratio in a direction of the wafer radius in a case of using a focus ring (i.e., a modified example of the focus ring of this embodiment) constituted by a SiC ring with a width of 5 cm and a radius (outside radius) of 15 cm and a Si ring with a width of 5 cm and a radius (outside radius) of 20 cm under etching conditions of this embodiment. Each of the CₓF_{y}/F ratios shown in FIGS. 11A and 11B is measured at a point 3 cm above the surface of the wafer (i.e., semiconductor substrate).

As shown in FIG. 11A, in the case of using the Si focus ring, the fluorine radicals are scavenged over the entire surface of the Si focus ring, so that the CₓF_{y}/F ratio increases sharply on the periphery of the wafer. Accordingly, the etching ratio of the oxide film, the selectivity between the oxide film and its underlying material or the etched shape, for example, changes sharply on the periphery of the wafer.

On the other hand, in the case of using the focus ring as the modified example of this embodiment constituted by the SiC ring and the Si ring, the reactivity between the SiC ring and the fluorine radicals is smaller than that between the Si ring and the fluorine radicals. Accordingly, unlike the distribution shown in FIG. 11A, no sharp change is observed on the periphery of the wafer in the distribution of the CₓF_{y}/F ratio in the direction of the wafer radius shown in FIG. 11B. In other words, the CₓF_{y}/F ratio distribution in the wafer-radius direction shown in FIG. 11B is substantially uniform even on the periphery of the wafer. That is, the CₓF_{y}/F ratio distribution in the wafer-radius direction is uniform as shown in FIG. 11B, so that the uniformity in the wafer surface regarding, for example, the etching ratio of the oxide film, the selectivity between the oxide film and its underlying material or the etched shape is improved. The reason why CₓF_{y}/F ratio distribution in the wafer-radius direction shown in FIG. 11B does not sharply decrease but is uniform even on the SiC ring is because of the influence of diffusion of the fluorine radicals.

In the second embodiment, the surface area of the focus ring 108 is adjusted by varying the combination of the three rings 108a through 108c with radiuses of 12 cm, 14 cm and 16 cm, respectively. However, the number and radiuses of rings for use in adjustment of the surface area of the focus ring 108 are not specifically limited as long as the focus ring 108 is constituted by at least two rings containing different materials as main components. It should be noted that the rings constituting the focus ring 108 are fit together with no gaps there between and the focus ring 108 has an opening whose diameter corresponds to the diameter of the wafer (substrate 150) at its center. Specifically, rings are combined such that the outer side of a ring with a smaller radius is in contact with the inner side of a ring with a larger radius, and the focus ring 108 is provided on the lower electrode 102 such that the inner side of the focus ring 108 is in contact with the edge of the substrate 150.

In the second embodiment, SiC is used as a main component of the second ring 108b i.e., as a material showing a low fluorine-radical scavenging ability. Alternatively, quartz (SiO₂), alumina (aluminum oxide: Al₂O₃) or yttrium oxide (Y₂O₃) may be used, for example. In such a case, the same effects are obtained.

In the second embodiment, the focus ring 108 includes at least the first ring 108a containing, as a main component, silicon showing a high fluorine-radical scavenging ability and the second ring 108b containing, as a main component, SiC showing a low fluorine-radical scavenging ability. However, even in a case where the etching object is not an oxide film, if a focus ring including at least a ring containing, as a main component, a material showing a high scavenging ability to an etchant for the etching object and a ring containing, as a main component, a material showing a low scavenging ability to the etchant is used, the same effects as in this embodiment are, of course, obtained.

In the second embodiment, at least one of the plurality of rings constituting the focus ring 108 preferably contains, as a main component, the same material as the etching object. Then, in the case of etching, for example, an oxide film (SiO₂ film), if a focus ring including a ring of SiO₂ is used, the effective area to be etched (the SiO₂ area) is the sum of the area of a portion of the oxide film to be etched (a portion under the opening of the resist mask) and the surface area of the SiO₂ ring. In other words, if the focus ring is formed using a ring containing, as a main component, the same material as the etching object, the effective etched area of the etching object having a low opening area ratio is increased. Accordingly, the amount of the etchant to be supplied to a portion of the etching object to be etched is made uniform, irrespective of the degree of the opening area ratio of the etching object. As a result, a plurality of etching objects with various opening area ratios are etched into desired etched shapes using the same dry etching apparatus.

In the second embodiment, C₄F₈ is used as a reactive gas (gas for plasma generation) for etching the oxide film. However, in the second embodiment, the type of the gas for plasma generation is not limited and may be a gas containing at least one of CF₄, CHF₃, C₄F₈, C₅F₈, C₄F₆ and C₂F₆.

In the second embodiment, the focus ring 108 is mounted on the lower electrode 102 of the dry etching apparatus including the lower and upper electrodes 102 and 103 to surround the substrate 150. However, the type of the dry etching apparatus to which the present invention is applied is not limited. Specifically, the focus ring of the present invention may be mounted on an electrode within a reaction chamber of an etching apparatus of an ECR type or an ICP type which does not have an upper electrode (but has an antenna and a coil). Even in such a case, the same effects as in this embodiment are obtained. In any type of the dry etching apparatus, the etching object such as a wafer may be, of course, mounted on an electrode with a support such as a pedestal interposed there between.

The dry etching apparatus and method of the second embodiment are not limited in application, but are effective especially when applied to oxide-film etching for forming a hard mask or a trench for, for example, interconnection.

What is claimed is:

1. An etching apparatus comprising:
a chamber having a gas inlet, a gas outlet, a place for setting an object to be etched, and a shield device provided on said place and surrounding said object to be etched,
wherein said shield device has an opening the size of which is determined by an opening area ratio to be etched.

2. The etching apparatus of claim 1, wherein said shield device allows etching gas to pass through said opening area.

3. The etching apparatus of claim 1, further comprising an upper electrode and a lower electrode, and
wherein said object to be etched is set between said upper electrode and said lower electrode.

4. The etching apparatus of claim 1, wherein said shield device has a circle shape.

5. The etching apparatus of claim 1, wherein said opening area ratio is a ratio of an area to be removed by etching with respect to an entire area before etching.

6. An etching apparatus comprising:
a chamber having a gas inlet, a gas outlet, a place for setting an object to be etched, and a shield device provided on said place and surrounding said object to be etched,
wherein said shield device comprises one shield unit or a combination of two or more shield units selected from a plurality of shield units having different opening sizes that said shield device has an opening size of which is determined by an opening area ratio to be etched.

7. The etching apparatus of claim 6, wherein said shield units having different size openings, opening of said shield device is adjusted by selection of utilizing shield units.

8. The etching apparatus of claim 6, wherein each of the plurality of shield units contains silicon as a main component.

9. The etching apparatus of claim 6, wherein the plurality of shield units include at least two shield units whose main components differ from each other.

10. The etching apparatus of claim 6, wherein the plurality of shield units include a first shield unit containing silicon as a main component and a second shield unit containing a material other than silicon as a main component.

11. The etching apparatus of claim 6, wherein said shield device allows etching gas to pass through said opening area.

12. The etching apparatus of claim 6, further comprising an upper electrode and a lower electrode, and wherein said object to be etched is set between said upper electrode and said lower electrode.

13. The etching apparatus of claim 6, wherein said material other than silicon contains at least one material selected from the group consisting of quartz (SiO₂), silicon carbide (SiC), aluminum oxide (Al₂O₃) and yttrium oxide (Y₂O₃).

14. The etching apparatus of claim 6, wherein the plurality of shield units include at least a shield unit containing, as a main component, the same material as the object to be etched.

15. The etching apparatus of claim 6, wherein the shield device has a circle shape.

16. An etching method using an etching apparatus including a shield device, said shield device having an opening area and provided on surrounds an object to be etched,
the method comprising the steps of:
mounting said object to be etched on a place;
introducing a gas into a chamber to generate a plasma of said gas and performing etching on said object to be etched; and
adjusting said size of said opening of said shield device by determining an opening area ratio to be etched, before performing an etching step.

17. The etching method of claim 16, wherein the step of adjusting said size of said opening of said shield device includes said step of selecting one shield unit or a combination of two or more shield units from a plurality of shield units having opening of different sizes that said opening of said shield device has a size which is determined by an opening area ratio to be etched.

18. The etching method of claim 16, wherein the plurality of shield units include at least two shield units whose main components differ from each other.

19. The etching method of claim 16, wherein said gas contains at least one gas selected from the group consisting of CF₄, CHF₃, C₄F₈, C₅F₅, C₄F₆ and C₂F₆.

20. The etching method of claim 16, wherein said shield device allows etching gas to pass through said opening area.

21. The etching method of claim 16, wherein said shield device has a circle shape.
